(19) United States
(12) Patent Application Publication
(10) Pub. No.: US 2025/0210395 A1
(43) Pub. Date: Jun. 26, 2025

(54) SUBSTRATE PROCESSING APPARATUS INCLUDING SUBSTRATE SUPPORT UNIT

(71) Applicant: SEMES CO., LTD., Cheonan-si (KR)

(72) Inventors: Kuk Saeng KIM, Cheonan-si (KR); Wan Hee JEONG, Cheonan-si (KR); Do Youn LIM, Cheonan-si (KR)

(73) Assignee: SEMES CO., LTD., Cheonan-si (KR)

(21) Appl. No.: 18/976,315

(22) Filed: Dec. 10, 2024

(30) Foreign Application Priority Data
Dec. 11, 2023 (KR) 10-2023-0178485

(51) Int. Cl. H01L 21/683; H01J 37/32

(52) U.S. Cl. CPC H01L 21/6833; H01J 37/32577; H01J 37/32669; H01J 37/32724; H01J 2237/002; H01J 2237/3343

(57) ABSTRACT

Proposed are a substrate support unit and a substrate processing apparatus including the same. The substrate support unit includes a dielectric plate on which a substrate is placed, a metal plate disposed under the dielectric plate, an RF plate disposed under the metal plate, and a plurality of coupling units configured to couple the metal plate and the RF plate to each other. The coupling units include a first member disposed on a lower surface of the metal plate, and a second member disposed in an upper surface of the RF plate and in contact with the first member. The first member and the second member are kinematically coupled to each other.

### CROSS REFERENCE TO RELATED APPLICATION

The present application claims priority to Korean Patent Application No. 10-2023-0178485, filed Dec. 11, 2023, the entire contents of which are incorporated herein for all purposes by this reference.

### BACKGROUND OF THE INVENTION

### Field of the Invention

The present disclosure relates generally to a substrate support unit and a substrate processing apparatus including the same. More particularly, the present disclosure relates to a substrate support unit for reducing a gap occurring between a metal plate and an RF plate.

### Description of the Related Art

Generally, a process for manufacturing a semiconductor device includes a deposition process for forming a film on a semiconductor substrate, a chemical/mechanical polishing process for planarizing the film, a photoresist process for forming a photoresist pattern on the film, an etching process for forming the film into a pattern having electrical characteristics by using the photoresist pattern, an ion implantation process for implanting specific ions into a predetermined region of the substrate, a cleaning process for removing impurities on the substrate, and an inspection process for inspecting the surface of the substrate on which the film or pattern is formed. The various processes for manufacturing a semiconductor device require a wide temperature range for processing a substrate.

In particular, in a semiconductor device including a stack of a plurality of layers, such as 3D NAND and DRAM, an aspect ratio (AR) has recently been increasing to improve the performance of the device, and to achieve this aspect ratio, a cryogenic process is required. By etching a substrate at a cryogenic temperature, trenches with smooth vertical sidewalls may be formed, and etch selectivity for etching one material versus another material may be improved, so the cryogenic process is attracting attention.

The cryogenic process relies on the use of fluid circulated through a substrate support unit. The substrate support unit may include a dielectric plate, a metal plate, and an RF plate. The metal plate and the RF plate are usually bolted to each other. A fluid supply block may be provided in the RF plate and may supply temperature control fluid to control the temperature of the substrate support unit. The fluid supply block may supply fluid to the metal plate placed on the upper portion of the RF plate, and the fluid supplied to the metal plate may be cooled and supplied according to a process. The fluid supply block experiences rapid temperature changes, and the rapid temperature changes cause deformation of the metal plate. This causes a gap to be formed between the metal plate and the RF plate, causing fluid to leak through the gap.

### SUMMARY OF THE INVENTION

Accordingly, the present disclosure has been made to solve the above problems occurring in the related art, and the present disclosure is intended to propose a substrate support unit for reducing a gap between a metal plate and an RF plate, and a substrate processing apparatus including the same.

Problems that the present disclosure seeks to solve are not limited to the problems mentioned above, and other problems not mentioned will be clearly understood by those skilled in the art from the description below.

In order to achieve the objectives of the present disclosure, a substrate support unit according to an embodiment of the present disclosure includes: a dielectric plate on which a substrate is placed; a metal plate disposed under the dielectric plate; an RF plate disposed under the metal plate; and a plurality of coupling units configured to couple the metal plate and the RF plate to each other, wherein the coupling units include: a first member disposed on a lower surface of the metal plate; and a second member disposed in an upper surface of the RF plate and in contact with the first member, wherein the first member and the second member are kinematically coupled to each other.

In an embodiment, the metal plate and the RF plate may include preload parts.

In an embodiment, the preload parts may be formed symmetrically with respect to a center of each of the metal plate and the RF plate.

In an embodiment, each of the preload parts may include: a magnet provided in the metal plate; and a yoke provided in the RF plate and configured to generate magnetic force with the magnet.

In an embodiment, the first member may have a hemispherical shape.

In an embodiment, the second member may include a groove, and the first member may be in contact with the groove.

In an embodiment, a contact point between the groove and the first member may include three or fewer contact points.

In an embodiment, a temperature control flow path for temperature control may be formed inside the metal plate, and the RF plate may include a fluid supply block for supplying temperature control fluid to the temperature control flow path.

In an embodiment, the fluid supply block may include: a heat transfer medium inlet configured to supply a heat transfer medium to the metal plate; and a heat transfer medium outlet configured to discharge the heat transfer medium from the metal plate.

In an embodiment, the fluid supply block may include: a coolant inlet configured to supply coolant to the metal plate al plate; and a coolant outlet to discharge the coolant from the metal plate.

A substrate processing apparatus according to an embodiment of the present disclosure includes: a chamber having a processing space formed therein; a substrate support unit disposed in the processing space and configured to support a substrate; a gas supply configured to supply gas required for a process to the processing space; and a plasma source configured to generate plasma from the supplied gas, wherein the substrate support unit includes: a dielectric plate on which the substrate is placed; a metal plate disposed under the dielectric plate; an RF plate disposed under the metal plate; and a plurality of coupling units configured to couple the metal plate and the RF plate to each other, wherein the coupling units include: a first member disposed on a lower surface of the metal plate; and a second member disposed in an upper surface of the RF plate and in contact with the first member, wherein the first member and the second member are kinematically coupled to each other.

In an embodiment, the first member may include a plurality of first members provided radially with respect to a center of the metal plate.

In an embodiment, the second member may include a plurality of second members provided radially with respect to a center of the RF plate.

In an embodiment, the metal plate and the RF plate may include preload parts.

In an embodiment, each of the preload parts may include: a magnet provided in the metal plate; and a yoke provided in the RF plate and configured to generate magnetic force with the magnet.

A substrate processing apparatus according to an embodiment of the present disclosure includes: a chamber having a processing space formed therein; a substrate support unit disposed in the processing space and configured to support a substrate; a gas supply unit configured to supply gas required for a process to the processing space; and a plasma source configured to generate plasma from the supplied gas, wherein the substrate support unit includes: a dielectric plate on which the substrate is placed; a metal plate disposed under the dielectric plate and including a temperature control flow path for temperature control; an RF plate disposed under the metal plate and including a fluid supply block for supplying temperature control fluid to the temperature control flow path; and a plurality of coupling units configured to couple the metal plate and the RF plate to each other, wherein the coupling units include: a first member having a hemispherical shape disposed on a lower surface of the metal plate; and a second member disposed in an upper surface of the RF plate and including a groove in contact with the first member, wherein the groove has three or fewer contact points with the first member, and the first member and the second member are kinematically coupled to each other.

In an embodiment, the first member and the second member may include a plurality of first members and a plurality of second members provided radially on the metal plate and the RF plate, respectively.

In an embodiment, the metal plate and the RF plate may include preload parts.

In an embodiment, the preload parts may be formed symmetrically with respect to a center of each of the metal plate and the RF plate.

In an embodiment, each of the preload parts may include: a magnet provided in the metal plate; and a yoke provided in the RF plate and configured to generate magnetic force with the magnet.

According to the present disclosure, the first member is formed on the metal plate and the second member is formed in the RF plate, and the first member and the second member are kinematically coupled to each other, thereby preventing the deformation of the metal plate due to a temperature change.

Accordingly, a gap occurring between the metal plate and the RF plate can be reduced, and since the gap is reduced, leakage of fluid can be prevented.

However, the effects of the present disclosure are not limited to those mentioned above, and other effects not mentioned can be clearly understood by those skilled in the art to which the present disclosure belongs from the drawings below.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view illustrating a substrate processing apparatus according to an embodiment of the present disclosure;

FIG. 2 is a cross-sectional view of a substrate support unit according to an embodiment of the present disclosure;

FIG. 3 is a view illustrating a fluid supply block according to an embodiment of the present disclosure;

FIG. 4 is a view illustrating a metal plate according to an embodiment of the present disclosure;

FIG. 5 is a view illustrating an RF plate according to an embodiment of the present disclosure; and

FIGS. 6, 7A, and 7B are views illustrating coupling units for coupling the metal plate and the RF plate to each other according to an embodiment of the present disclosure.

### DETAILED DESCRIPTION OF THE INVENTION

Hereinafter, with reference to the accompanying drawings, embodiments of the present disclosure will be described in detail so that a person having ordinary knowledge in the technical field to which the present disclosure belongs can easily practice the embodiments. However, the present disclosure may be implemented in several different forms and is not limited to the embodiments described herein.

In describing the embodiments of the present disclosure, if it is determined that a specific description of a related known function or configuration may unnecessarily obscure the gist of the present disclosure, the specific description is omitted, and parts in which similar functions or operations are performed will use the same reference numerals throughout the drawings.

Since at least some of terms used in this specification are defined in consideration of functions in the present disclosure, the definition thereof may vary depending on users, operator intentions, and customs, etc. Therefore, the terms should be interpreted on the basis of contents throughout the specification.

In addition, in this specification, singular forms also include plural forms unless specifically stated otherwise in a phrase. In the specification, when it is said to include a certain component, this means that it may further include other components without excluding the other components unless otherwise stated.

Meanwhile, in the drawings, the size and shape of component, and the thickness of a line may be somewhat exaggerated for convenience of understanding.

Hereinafter, the embodiments of the present disclosure will be described in detail with reference to the accompanying drawings. In the description with reference to the accompanying drawings, the same or corresponding components regardless of reference numerals are given the same reference numerals, and redundant descriptions thereof are omitted.

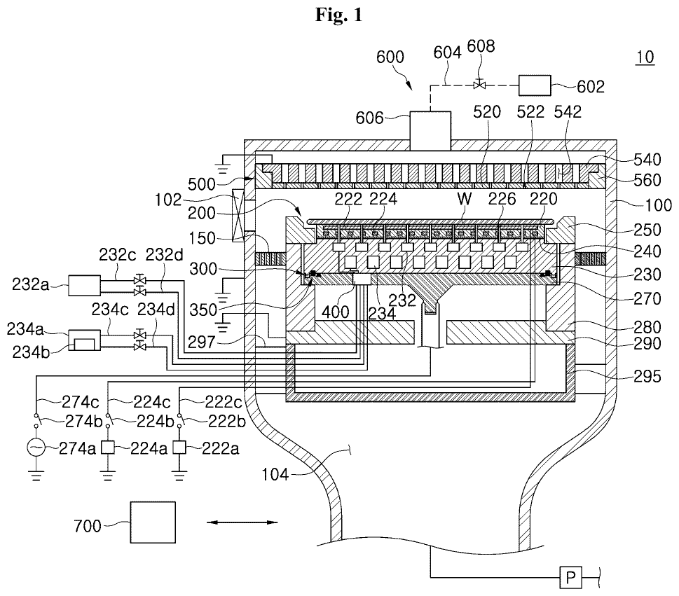

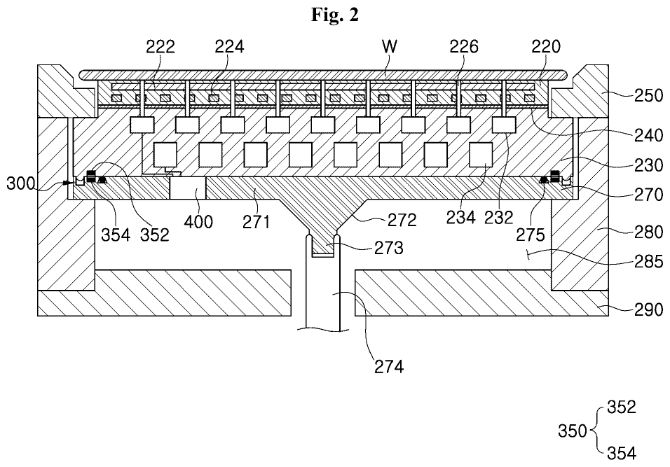

FIG. 1 is a view illustrating a substrate processing apparatus according to an embodiment of the present disclosure, and FIG. 2 is a view illustrating a substrate support unit according to an embodiment of the present disclosure.

Referring to FIGS. 1 and 2, a substrate processing apparatus 10 may include a chamber 100, a substrate support unit 200, coupling units 300, preload parts 350, a fluid supply block 400, a shower head unit 500, a gas supply unit 600, a plasma source, and a control unit 700.

The chamber 100 has a processing space in which a plasma process is performed. The chamber 100 may be provided in a sealed shape and may be made of a conductive material. For example, the chamber 100 may be made of a material including metal. The chamber 100 may be made of an aluminum material and may be grounded. An exhaust hole 104 can be formed on the bottom surface of the chamber 100. The exhaust hole 104 may be connected to an exhaust line, and the exhaust line may be connected to a pump P. The exhaust hole 104 may discharge reaction byproducts generated during a process and gases remaining inside the chamber 100 to the outside of the chamber 100. In this case, the internal space of the chamber 100 may be depressurized to a predetermined pressure.

The chamber 100 may have an opening part 102 formed in a side wall thereof. The opening part 102 may function as a passage for a substrate W to go into and out of the chamber 100. The opening part 102 may be configured to be opened and closed by a door assembly.

A baffle unit 150 may be provided between the inner wall of the chamber 100 and the substrate support unit 200. The baffle unit 150 may be provided in an annular ring shape, and may include a plurality of through holes formed therein. Gas supplied into the chamber 100 may pass through the through holes of the baffle unit 150 and be exhausted through the exhaust hole 104. The flow of gas may be controlled depending on the shape of the baffle unit 150 and the number of through holes.

The substrate support unit 200 may be disposed in the lower area of the interior of the chamber 100. The substrate support unit 200 may support the substrate W by electrostatic force. However, this embodiment is not limited thereto, and the substrate W may be supported in various methods, such as mechanical clamping, and vacuum, etc. Hereinafter, the substrate support unit 200 including an electrostatic chuck ESC will be described.

As illustrated in FIGS. 1 and 2, the substrate support unit 200 according to an embodiment of the present disclosure may include a dielectric plate 220, the metal plate 230, a focus ring 250, an RF plate 270, an insulation cover 280, a base plate 290, and a lower cover 295.

The dielectric plate 220 is located at the upper end part of the substrate support unit 200. The dielectric plate 220 is provided as a dielectric substance in the shape of a disc. The substrate W is placed on the upper surface of the dielectric plate 220. An electrode 222, a heater 224, and a supply flow path 226 may be formed inside the dielectric plate 220. The supply flow path 226 may be formed through the upper surface of the dielectric plate 220 from the lower surface of the dielectric plate 220. The supply flow path 226 may include a plurality of supply flow paths formed by being spaced apart from each other, and may be provided as a passage through which a heat transfer medium is supplied to the lower surface of the substrate W.

The electrode 222 provided in the dielectric plate 220 may be located above the heater 224. The electrode 222 may be electrically connected to a first lower power source 222a and may include a direct current power source. A switch 222b may be installed between the electrode 222 and the first lower power source 222a. The electrode 222 may be electrically connected to/disconnected from the first lower power source 222a by turning the switch 222b on/off. When the switch is turned on, a direct current is applied to the electrode 222. An electrostatic force may be generated between the electrode 222 and the substrate W by the current applied to the electrode 222, and the substrate W may be adsorbed to the dielectric plate 220 by the electrostatic force.

The heater 224 may be electrically connected to a second lower power source 224a. A switch 224b may be installed between the heater 224 and the second lower power source 224a. The heater 224 may be electrically connected to/disconnected from the second lower power source 224a by turning the switch 224b on/off. The heater 224 generates heat by resisting a current applied from the second lower power source 224a. The generated heat may be transferred to the substrate W through the dielectric plate 220. The substrate W is maintained at a predetermined temperature by the heat generated from the heater 224. The heater 224 may include a spiral-shaped coil.

The metal plate 230 is located under the dielectric plate 220. The lower surface of the dielectric plate 220 and the upper surface of the metal plate 230 may be bonded to each other by adhesive 240. The metal plate 230 may be made of aluminum material. A first flow path 232 and a second flow path 234 may be formed inside the metal plate 230.

The metal plate 230 may be connected to a high-frequency power source through a high-frequency transmission line and the RF plate 270. The metal plate 230 may be powered by the high-frequency power source to smoothly supply plasma generated in the processing space to the substrate W. That is, the metal plate 230 may function as an electrode. In addition, in FIG. 1, the substrate processing apparatus 10 is configured as a capacitively coupled plasma (CCP) type, but is not limited thereto. The substrate processing apparatus 10 according to an embodiment of the present disclosure may be configured as an inductively coupled plasma (ICP) type.

The first flow path 232 may be provided as a passage through which a heat transfer medium circulates. A heat transfer medium supplied from a heat transfer medium supply part 232a may be supplied to a fluid supply block 400 through a heat transfer medium supply line 232c. In addition, the heat transfer medium may be introduced back to the heat transfer medium supply part 232a through a heat transfer medium recovery line 232d. A valve may be formed in each of the heat transfer medium supply line 232c and the heat transfer medium recovery line 232d. The heat transfer medium may be supplied to the first flow path 232 through the fluid supply block 400. For example, the heat transfer medium may be helium He, but is not limited thereto. The heat transfer medium may be delivered to the supply flow path 226 through the first flow path 232 and may be supplied to the lower surface of the substrate W.

The second flow path 234 may be provided as a passage through which a coolant circulates. The second flow path 234 may be formed under the first flow path 232. A coolant supplied from a coolant supply part 234a may be supplied to the second flow path 234 through the fluid supply block 400 via a coolant supply line 234c. In addition, the coolant may be introduced back to the coolant supply part 234a through a coolant recovery line 234d. A valve may be formed in each of the coolant supply line 234c and the coolant recovery line 234d. The coolant supply part 234a may be provided with a cooler 234b, and the cooler 234b may cool a coolant to a predetermined temperature. The coolant supplied to the second flow path 234 may circulate along the second flow path 234 and cool the metal plate 230. The metal plate 230 may cool the dielectric plate 220 and the substrate W together while the metal plate 230 is cooled, thereby maintaining the substrate W at a predetermined temperature.

The focus ring 250 may be disposed on an edge area of the electrostatic chuck. The focus ring 250 may have a ring shape and may be arranged along the periphery of the dielectric plate 220. In addition, the focus ring 250 may be disposed on the upper surface of the insulation cover 280. The focus ring 250 may control an electromagnetic field so that the density of plasma is uniformly distributed over the entire area of the substrate W. Accordingly, plasma is uniformly formed over the entire area of the substrate W, so that each area of the substrate W may be uniformly etched.

An air gap 285 may be formed under the metal plate 230. The air gap 285 is formed between the RF plate 270 and the base plate 290 to be described later. The air gap 285 may be surrounded by the insulation cover 280. The air gap 285 electrically insulates the RF plate 270 from the base plate 290.

The RF plate 270 is provided under the metal plate 230. The upper surface of the RF plate 270 may be provided to be in contact with the lower surface of the metal plate 230. In addition, a sealing member 275 may be formed between the metal plate 230 and the RF plate 270 for sealing. According to an embodiment of the present disclosure, the sealing member 275 may be an O-ring, but is not limited thereto. The plane of the RF plate 270 may be provided in the shape of a circular plate. The RF plate 270 may be made of a conductive material, for example, aluminum. According to an embodiment of the present disclosure, each of the coupling units 300 and each of the preload parts 350 may be provided to couple the metal plate 230 and the RF plate 270 to each other. The coupling unit 300 and the preload part 350 of the present disclosure will be described in detail later. In addition, the fluid supply block 400 may be formed in the RF plate 270.

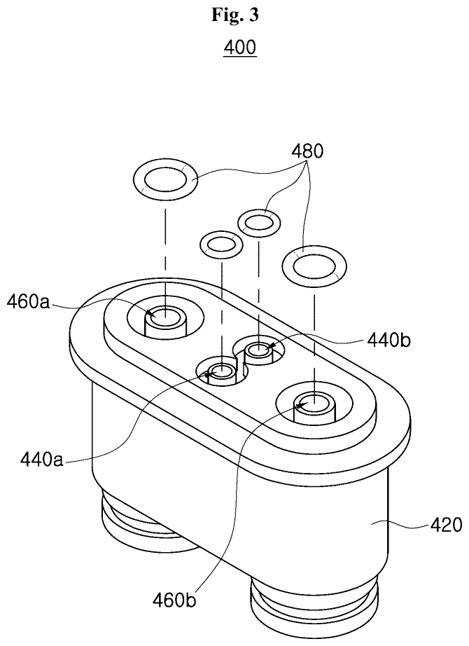

FIG. 3 is a view illustrating a fluid supply block according to an embodiment of the present disclosure.

Referring to FIG. 3, the fluid supply block 400 may include a main body 420, heat transfer medium supply paths 440a and 440b, and coolant supply paths 460a and 460b.

The main body 420 may be formed in the RF plate 270. The main body 420 may be made of engineering plastic such as polyetheretherketone (PEEK), Teflon, Vespel, Celazole, and perfluoroalkoxy (PFA). The heat transfer medium supply paths 440a and 440b and the coolant supply paths 460a and 460b may be formed inside the main body 420.

One of the heat transfer medium supply paths 440a and 440b serves as a heat transfer medium inlet. For example, the heat transfer medium supply path 440a may serve as a heat transfer medium inlet, and the heat transfer medium inlet 440a may receive a heat transfer medium, such as helium He, from the heat transfer medium supply part 232a and may supply the heat transfer medium to the first flow path 232 of the metal plate 230. In addition, another of the heat transfer medium supply paths 440a and 440b may serve as a heat transfer medium outlet. For example, the heat transfer medium supply path 440b may serve as a heat transfer medium outlet, and the heat transfer medium outlet 440b may receive a heat transfer medium, such as helium, from the first flow path 232 of the metal plate 230 and may discharge the heat transfer medium to the heat transfer medium supply part 232a.

One of the coolant supply paths 460a and 460b may serve as a coolant inlet. For example, the coolant supply path 460a may serve as a coolant inlet, and the coolant inlet 460a may receive a coolant from the coolant supply part 234a and may supply the coolant to the second flow path 234 of the metal plate 230. In addition, another of the coolant supply paths 460a and 460b may serve as a coolant outlet. For example, the coolant supply path 450b may serve as a coolant outlet, and the coolant outlet 460b may receive a coolant from the second flow path 234 of the metal plate 230 and may discharge the coolant to the coolant supply part 234a.

Each of the heat transfer medium inlet 440a, the heat transfer medium outlet 440b, the coolant inlet 460a, and the coolant outlet 460b may be provided with a sealing member 480 to prevent fluid leakage. The sealing member 480 may be an O-ring, but is not limited thereto.

Referring back to FIGS. 1 and 2, the RF plate 270 may include an electrode plate part 271, a deformed part 272, and a rod coupling part 273. The plane of the electrode plate part 271 is provided in a shape corresponding to the shape of the plane of the metal plate 230. The deformed part 272 is formed by extending downward from the center of the electrode plate part 271. The deformed part 272 may be formed to have a diameter decreasing gradually downward. The rod coupling part 273 is formed by extending from the lower end of the deformed part 272.

A power supply rod 274 may supply power to the RF plate 270. The power supply rod 274 may be electrically connected to the RF plate 270. The power supply rod 274 may be connected to a third lower power source 274a. The third lower power source 274a may be provided as an RF power source that generates RF power. The power supply rod 274 receives high frequency power from the third lower power source 274a. The power supply rod 274 may be made of a conductive material. For example, the power supply rod 274 may be made of a material including metal. In addition, the power supply rod 274 may be connected to a matcher (not shown). The third lower power source 274a and the power supply rod 274 may be connected via the matcher (not shown). The matcher (not shown) may perform impedance matching.

The insulation cover 280 may support the RF plate 270. The insulation cover 280 may be provided to be in contact with the side surface of the RF plate 270. The insulation cover 280 may be provided to be in contact with the edge area of the lower surface of the RF plate 270. For example, the insulation cover 280 may have a tubular shape with open upper and lower parts. In addition, the insulation cover 280 may have a stepped inner side so that the RF plate 270 may be supported by the insulation cover 280. The insulation cover 280 may be made of a material having an insulating property.

The base plate 290 is configured to be electrically grounded. A through hole through which the power supply rod 274 passes may be formed in the center of the base plate 290.

The lower cover 295 may be positioned on the lower end of the substrate support unit 200. The lower cover 295 may be located by being spaced apart upward from the lower part of the chamber 100. The lower cover 295 may have a space with an open upper surface formed inside. The upper surface of the lower cover 295 may be covered by the base plate 290. Accordingly, The outer radius of the cross-section of the lower cover 295 may be provided to have the same length as the outer radius of the base plate 290. A lift pin assembly (not shown), etc. may be located in the internal space of the lower cover 295.

The lower cover 295 may include a connecting member 297. The connecting member 297 may connect the outer side surface of the lower cover 295 with the inner side wall of the chamber 100. The connecting member 297 may include a plurality of connecting members formed at predetermined distances on the outer side surface of the lower cover 295. The connecting members 297 may support the substrate support unit 200 within the chamber 100. In addition, the connecting member 297 may be connected to the inner side wall of the chamber 100 so that the lower cover 295 is electrically grounded. A first power line 222c connected to the first lower power source 222a, a second power line 224c connected to the second lower power source 224a, a third power line 274c connected to the third lower power source 274a, the heat transfer medium supply line 232c connected to the heat transfer medium supply part 232a, and the coolant supply line 234c connected to the coolant supply part 234a may extended into the lower cover 295 through the interior spaces of the connecting members 297, respectively.

The lower cover 295 may be disposed under the insulation cover 280. The lower cover 295 may be disposed under the insulation cover 280 to support the insulation cover 280. The lower cover 295 may be made of a conductive material. For example, the lower cover 295 may be made of a material including metal. In addition, the lower cover 295 may be electrically connected to the chamber 100. The lower cover 295 may be electrically grounded.

The shower head unit 500 may disperse gas supplied from above. In addition, the shower head unit 500 may supply gas supplied by the gas supply unit 600 evenly to the processing space. The shower head unit 500 may include a shower head 520 and a gas spray plate 540.

The shower head 520 may be disposed under the gas spray plate 540. The shower head 520 may be located by being spaced apart by a predetermined distance downward from the upper surface of the chamber 100. The shower head 520 may be located above the substrate support unit 200. The shower head 520 and the upper surface of the chamber 100 may have a constant space defined therebetween. The shower head 520 may be provided in a plate shape with a constant thickness. The lower surface of the shower head 520 may be anodized to prevent arc generation due to plasma. The shower head 520 may have a plurality of gas supply holes 522 formed therein. Each of the gas supply holes 522 may be formed by vertically penetrating the upper and lower surfaces of the shower head 520.

The gas spray plate 540 may be disposed on the upper part of the shower head 520. The gas spray plate 540 may be located by being spaced apart by a predetermined distance from the upper surface of the chamber 100. The gas spray plate 540 may diffuse gas supplied from above. The gas spray plate 540 may have gas introduction holes 542 formed therein. Each of the gas introduction holes 542 may be formed at a position corresponding to the gas supply hole 522. The gas introduction hole 542 may communicate with the gas supply hole 522. Gas supplied from the upper side of the shower head unit 500 may sequentially pass through the gas introduction hole 542 and the gas supply hole 522 and be supplied to the lower side of the shower head 520. The gas spray plate 540 may include a metal material. The gas spray plate 540 may be grounded and may function as an upper electrode.

An insulating ring 560 may be arranged to surround the peripheries of the shower head 520 and the gas spray plate 540. The insulating ring 560 may be provided in an overall annular ring shape. The insulating ring 560 may be made of a non-metallic material.

The gas supply unit 600 may supply gas required for a process to the chamber 100. The gas supply unit 600 may include a gas supply source 602, a gas supply line 604, and a gas supply nozzle 606. The gas supply nozzle 606 may be installed in the central part of the upper end of the chamber 100. A spray port may be formed in the lower surface of the gas supply nozzle 606. Gas supplied through the gas supply nozzle 606 may be supplied to the processing space inside the chamber 100 through the shower head unit 500. The gas supply line 604 may connect the gas supply nozzle 606 with the gas supply source 602. A gas supply valve 608 may be installed on the gas supply line 604 to open or close the passage of the gas supply line 604 or to control the flow rate of fluid flowing through the passage.

FIG. 1 illustrates one gas supply source 602, one gas supply line 604, and one gas supply valve 608, but the gas supply source of the present disclosure may include a plurality of gas supply sources to supply a plurality of gases to the chamber 100, and the gas supply valve of the present disclosure may include a plurality of gas supply valves to independently control the supply of each of the gases.

The plasma source may excite gas in the chamber 100 to a plasma state. In an embodiment of the present disclosure, a capacitively coupled plasma (CCP) source is used. When using the capacitively coupled plasma source, the interior of the chamber 100 may include an upper electrode and a lower electrode. According to an embodiment of the present disclosure, the upper electrode may be the shower head unit 500 and the lower electrode may be provided as a combination of the metal plate 230 and the RF plate 270. High frequency power may be applied to the lower electrode, and the upper electrode may be grounded.

The control unit 700 may comprehensively control the operation of the substrate processing apparatus 10 configured as described above. The control unit 700 is, for example, a computer and may be provided with a central processing unit (CPU), random access memory (RAM), read only memory (ROM), and an auxiliary memory device, etc. The CPU operates based on programs stored in the ROM or auxiliary memory device, or process conditions, and may control the operation of the entirety of the substrate processing apparatus 10. In addition, a computer-readable program required for control may be stored in a storage medium. A memory medium may, for example, include examples such as a flexible disk, a compact disc (CD), CD-ROM, hard disk, flash memory, or DVD, etc. The control unit 700 may be installed inside or outside the substrate processing apparatus 10. When the control unit 700 is provided outside the substrate processing apparatus 10, the control unit 700 may control the substrate processing apparatus 10 by wired or wireless communication means.

The control unit 700 according to an embodiment of the present disclosure may control gas to be supplied to the processing space inside the chamber 100 and the supplied gas to be converted into plasma. The control unit 700 may control the temperature of a coolant supplied to the metal plate 230 according to a process by controlling the cooler 234b connected to the fluid supply block 400.

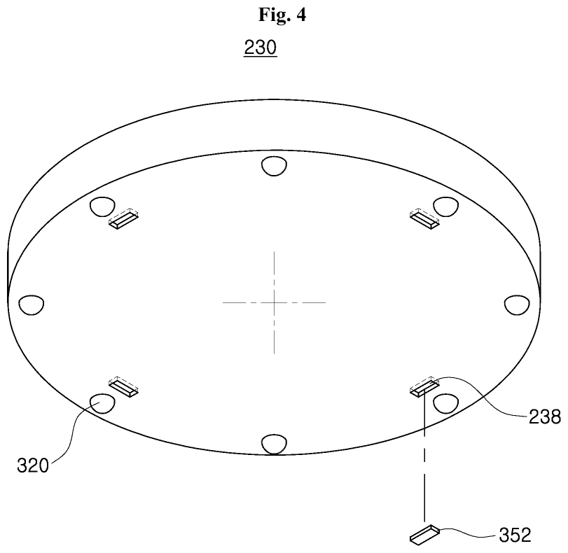

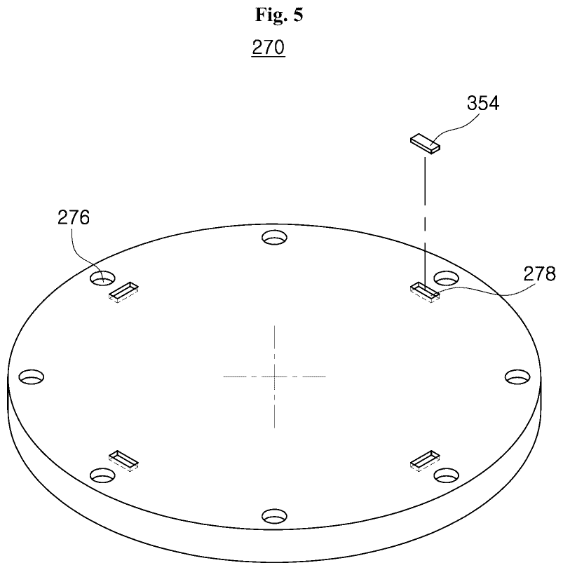

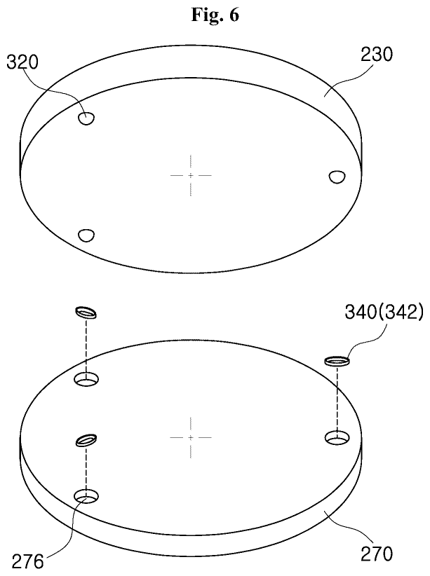

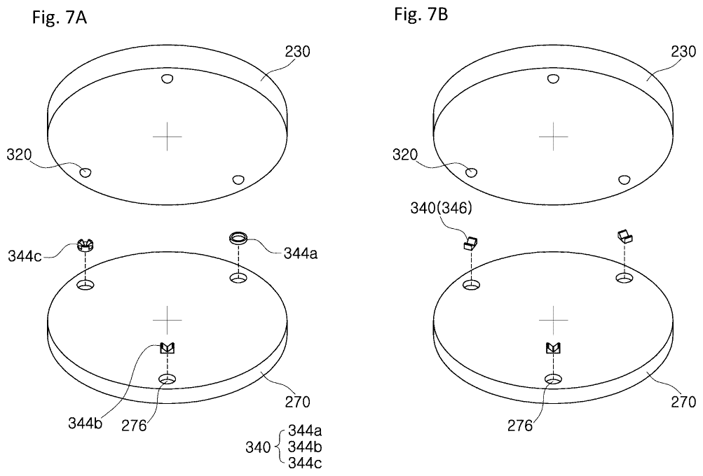

FIGS. 4 and 5 are views illustrating the metal plate and the RF plate according to an embodiment of the present disclosure, and FIGS. 6, 7A, and 7B are views illustrating the coupling unit for coupling the metal plate and the RF plate to each other.

FIG. 4 is a view illustrating the lower surface of the metal plate, and the lower surface is a surface on which the metal plate is coupled to the RF plate.

Referring to FIG. 4, magnets 352 of the preload parts 350 and a first member 320 of the coupling unit 300 to be described later may be provided on the metal plate 230 according to an embodiment of the present disclosure. According to an embodiment of the present disclosure, a magnet accommodation groove 238 may be formed in the metal plate 230 to accommodate each of the magnets 352 of the preload parts 350. The magnet accommodation groove 238 may be provided to be spaced apart from the first member 320 by a predetermined distance, and may include a plurality of magnet accommodation grooves formed in the metal plate 230. The magnets 352 of the preload parts 350 according to an embodiment of the present disclosure may be formed symmetrically with respect to the center of the metal plate 230. According to the present disclosure, the magnet is illustrated to include four magnets 352 arranged on the metal plate 230, but is not limited thereto. The first member 320 may be provided by protruding from the metal plate 230 and may include a plurality of first members provided radially with respect to the center of the metal plate 230.

FIG. 5 is a view illustrating the upper surface of the RF plate according to an embodiment of the present disclosure, wherein the upper surface is a surface that is coupled to the metal plate.

Referring to FIG. 5, the RF plate 270 according to an embodiment of the present disclosure may have yokes 354 of the preload parts 350 and member accommodation grooves 276 to accommodate second members 340 of the coupling unit 300 to be described later. A yoke accommodation groove 278 for accommodating each of the yokes 354 may be provided at a position opposite to the magnet accommodation groove 238 formed in the metal plate 230, and may include a plurality of yoke accommodation grooves formed in the RF plate 270. The yokes 354 of the preload parts 350 according to an embodiment of the present disclosure may be formed symmetrically with respect to the center of the RF plate 270. According to the present disclosure, the yoke 354 is illustrated to include four yokes 354 arranged in the RF plate 270, but is not limited thereto. Each of the member accommodation grooves 276 for accommodating each of the second members 340 may be formed at a position opposite to the first member 320, and the second members 340 and the member accommodation grooves 276 may are formed or arranged radially with respect to the center of the RF plate 270.

According to an embodiment of the present disclosure, a magnetic force is generated between the magnet 352 and the yoke 354 of the preload part 350, and the occurrence of a gap between the metal plate 230 and the RF plate 270 due to heat may be prevented by using this magnetic force. In addition, the magnet 352 and the yoke 354 are illustrated to be rod-shaped, but are not limited thereto.

FIG. 6 is a view illustrating a coupling unit for coupling the metal plate and the RF plate to each other according to an embodiment of the present disclosure.

Referring to FIG. 6, the coupling unit 300 of the present disclosure may include the first member 320 and the second member 340, and the first member 320 and the second member 340 may be kinematically coupled to each other. The kinematic coupling of the present invention affects the motion or direction of the first member and the second member. Specifically, the first member can change its position while in contact with the second member. The position of the first member can change due to heat, and the position of the first member can change as long as it does not separate from the second member. In some embodiments, the “kinematically coupled” may refer to “movably coupled”.

The first member 320 may be inserted into the member accommodation groove 276 of the RF plate 270 and may be in contact with the second member 340. The first member 320 according to an embodiment of the present disclosure may have a hemispherical shape but is not limited thereto. The first member 320 may be in contact with a groove 342 of the second member 340 to have a contact point.

The second member 340 may have the groove 342 that is in contact with the first member 320. The first member 320 may move along the groove 342 of the second member 340. As illustrated in FIG. 6, the second member 340 according to an embodiment of the present disclosure may include the groove 342 having two to three contact points with the first member 320, and may have an oval shape. The groove 342 of the second member 340 may have any shape as long as the groove 342 has two to three points of contact with the first member 320. The second member 340 of an oval shape may include three second members formed in the RF plate 270. The metal plate 230 and the RF plate 270 have different degrees of deformation due to heat. Accordingly, the second member 340 of an oval shape may be formed so that the first member 320 is prevented from being removed from the second member 340. Specifically, the second member 340 has an oval shape including the groove 342, and thus even if the metal plate 230 is more deformed due to heat than the RF plate 270, the first member 320 of the metal plate 230 may move along the longitudinal direction of the second member 340 of the RF plate 270, and the first member 320 may be prevented from being removed from the second member 340.

A structure between the first member 320 and the second member 340 according to an embodiment of the present disclosure is an application of kinematic coupling, and FIG. 6 is an application of quasi-kinematic coupling.

In addition, as illustrated in FIG. 7A, the grooves 344a, 344b, and 344c of the second member 340 may have one to three contact points with the first member 320. The groove 344a of the second member 340 may have a flat bottom surface to have one contact point with the first member 320. The groove 344b of the second member 340 may have a “V” shape in a cross-section to have two contact points with the first member 320. The groove 344c of the second member 340 may have a concave tetrahedral shape to have three contact points with the first member 320.

Alternatively, as illustrated in FIG. 7B, the second member 340 may have a groove 346 having a radially extending “V” shape and may have two contact points with the first member 320.

According to an embodiment of the present disclosure, structure between the first member 320 and the second member 340 applies kinematic coupling. FIG. 7A illustrates Kelvin coupling, and FIG. 7B illustrates Maxwell coupling.

According to an embodiment of the present disclosure, the coupling unit 300 coupled by quasi-kinematic coupling may include three coupling units formed on the metal plate 230 and the RF plate 270. In addition, coupling units 300 other than the coupling unit 300 coupled by quasi-kinematic coupling may be coupled by Kelvin coupling and Maxwell coupling, but are not limited thereto. For example, the remaining coupling units 300 may be used in combination with Kelvin coupling and Maxwell coupling. When using a combination of Kelvin coupling and Maxwell coupling, the groove 344c of the second member 340 having three contact points may include two grooves, and the groove 344b or 346 of the second member 340 having two contact points may include three grooves.

Accordingly, by applying kinematic coupling to the coupling unit 300 for coupling the metal plate 230 and the RF plate 270 to each other, the accuracy of alignment between the metal plate 230 and the RF plate 270 can be improved. That is, even if the deformation of each of the metal plate 230 and the RF plate 270 occurs differently due to heat, the first member 320 is prevented from being detached from the second member 340, thereby improving coupling between the metal plate 230 and the RF plate 270.

As described above, the metal plate and the RF plate may be coupled to each other by using the coupling unit and the preload part. More specifically, the coupling unit may include the first member having a hemispherical shape and the second member having one to three contact points with the first member. The first member may be provided on the metal plate, and the second member may be provided in the RF plate, wherein the first member and the second member may be kinematically coupled to each other. By causing more deformation of the metal plate and the RF plate in a horizontal direction due to heat by the first member and the second member, deformation thereof in a vertical direction may be reduced. Therefore, a gap that occurs between the metal plate and the RF plate due to temperature difference may be reduced, and fluid leaking into the gap may be prevented, thereby improving productivity.

In addition, even if the metal plate and the RF plate are deformed in the horizontal direction due to heat, the first member may be in continuous contact with the second member. This may improve coupling between the metal plate and the RF plate.

The above description is only an exemplary description of the technical idea of the present disclosure, and the present disclosure may be variously modified and varied to a person having ordinary knowledge in the technical field to which the present disclosure belongs without departing from the essential characteristics of the present disclosure. Accordingly, the embodiments described in the present disclosure are not intended to limit the technical idea of the present disclosure, but to explain, and the technical idea of the present disclosure is not limited by these embodiments. The scope of protection of the present disclosure should be interpreted according to the scope of the claims below, and all technical ideas within the scope equivalent thereto should be construed as being included in the scope of claims of the present disclosure.

What is claimed is:

1. A substrate support unit comprising:
a dielectric plate on which a substrate is placed;
a metal plate disposed under the dielectric plate;
an RF plate disposed under the metal plate; and
a plurality of coupling units configured to couple the metal plate and the RF plate to each other,
wherein the plurality of coupling units include:
a first member disposed on a lower surface of the metal plate; and
a second member disposed in an upper surface of the RF plate and in contact with the first member, and
wherein the first member and the second member are kinematically coupled to each other.

2. The substrate support unit of claim 1,
wherein the metal plate and the RF plate include preload parts.

3. The substrate support unit of claim 2,
wherein the preload parts are formed symmetrically with respect to a center of each of the metal plate and the RF plate.

4. The substrate support unit of claim 3,
wherein each of the preload parts includes:
a magnet provided in the metal plate; and
a yoke provided in the RF plate and configured to generate magnetic force with the magnet.

5. The substrate support unit of claim 1,
wherein the first member has a hemispherical shape.

6. The substrate support unit of claim 1,
wherein the second member includes a groove, and the first member is in contact with the groove.

7. The substrate support unit of claim 6,
wherein a contact point between the groove and the first member includes three or fewer contact points.

8. The substrate support unit of claim 1,
wherein a temperature control flow path for temperature control is formed inside the metal plate, and
wherein the RF plate includes a fluid supply block for supplying temperature control fluid to the temperature control flow path.

9. The substrate support unit of claim 8,
wherein the fluid supply block includes:
a heat transfer medium inlet configured to supply a heat transfer medium to the metal plate; and
a heat transfer medium outlet configured to discharge the heat transfer medium from the metal plate.

10. The substrate support unit of claim 8,
wherein the fluid supply block includes:
a coolant inlet configured to supply coolant to the metal plate al plate; and
a coolant outlet to discharge the coolant from the metal plate.

11. A substrate processing apparatus comprising:
a chamber having a processing space formed therein;
a substrate support unit disposed in the processing space and configured to support a substrate;
a gas supply unit configured to supply gas required for a process to the processing space; and
a plasma source configured to generate plasma from the supplied gas,
wherein the substrate support unit includes:
a dielectric plate on which the substrate is placed;
a metal plate disposed under the dielectric plate;
an RF plate disposed under the metal plate; and
a plurality of coupling units configured to couple the metal plate and the RF plate to each other,
wherein the plurality of coupling units include:
a first member disposed on a lower surface of the metal plate; and
a second member disposed in an upper surface of the RF plate and in contact with the first member, and
wherein the first member and the second member are kinematically coupled to each other.

12. The substrate processing apparatus of claim 11,
wherein the first member includes a plurality of first members provided radially with respect to a center of the metal plate.

13. The substrate processing apparatus of claim 11,
wherein the second member includes a plurality of second members provided radially with respect to a center of the RF plate.

14. The substrate processing apparatus of claim 11,
wherein the metal plate and the RF plate include preload parts.

15. The substrate processing apparatus of claim 14,
wherein each of the preload parts includes:
a magnet provided in the metal plate; and
a yoke provided in the RF plate and configured to generate magnetic force with the magnet.

16. A substrate processing apparatus comprising:
a chamber having a processing space formed therein;
a substrate support unit disposed in the processing space and configured to support a substrate;
a gas supply unit configured to supply gas required for a process to the processing space; and
a plasma source configured to generate plasma from the supplied gas,
wherein the substrate support unit includes:
a dielectric plate on which the substrate is placed;
a metal plate disposed under the dielectric plate and including a temperature control flow path for temperature control;
an RF plate disposed under the metal plate and including a fluid supply block for supplying temperature control fluid to the temperature control flow path; and
a plurality of coupling units configured to couple the metal plate and the RF plate to each other,
wherein the coupling units include:
a first member having a hemispherical shape disposed on a lower surface of the metal plate; and
a second member disposed in an upper surface of the RF plate and including a groove in contact with the first member, and
wherein the groove has three or fewer contact points with the first member, and the first member and the second member are kinematically coupled to each other.

17. The substrate processing apparatus of claim 16,
wherein the first member and the second member include a plurality of first members and a plurality of second members provided radially on the metal plate and the RF plate, respectively.

18. The substrate processing apparatus of claim 16,
wherein the metal plate and the RF plate include preload parts.

19. The substrate processing apparatus of claim 18,
wherein the preload parts are formed symmetrically with respect to a center of each of the metal plate and the RF plate.

20. The substrate processing apparatus of claim 19,
wherein each of the preload parts includes:
a magnet provided in the metal plate; and
a yoke provided in the RF plate and configured to generate magnetic force with the magnet.
